(19) United States
(12) Patent Application Publication
(10) Pub. No.: US 2026/0214921 A1
(43) Pub. Date: Jul. 23, 2026

(54) HIGH PERFORMANCE SCHOTTKY BARRIER DIODE

(71) Applicant: Microchip Technology Incorporated, Chandler, AZ (US)

(72) Inventors: Shesh Mani Pandey, Gilbert, AZ (US); Randy L. Yach, Phoenix, AZ (US)

(73) Assignee: Microchip Technology Incorporated, Chandler, AZ (US)

(21) Appl. No.: 19/455,473

(22) Filed: Jan. 21, 2026

Related U.S. Application Data
(60) Provisional application No. 63/748,793, filed on Jan. 23, 2025.

(51) Int. Cl. H10D 8/60; H10D 8/01; H10D 62/10; H10D 62/832; H10D 64/64

(52) U.S. Cl. CPC H10D 8/60; H10D 8/051; H10D 62/124; H10D 62/8325; H10D 64/64

(57) ABSTRACT

A Schottky barrier diode (SBD) includes a volume of semiconductor material, a plurality of laterally spaced pockets of doped material, and a silicon layer. The volume of semiconductor material presents opposite first and second ends. The plurality of laterally spaced pockets of doped material extend into the volume of semiconductor material adjacent the first end. The silicon layer is located adjacent the first end between the pockets of doped material.

### CROSS-REFERENCE TO RELATED APPLICATIONS

The current patent application claims the benefit under 35 U.S.C. § 119(e) of the priority date of U.S. Provisional Application Ser. No. 63/748,793; titled "HIGH PERFORMANCE SCHOTTKY BARRIER DIODE"; and filed January 23, 2025. The Provisional Application is hereby incorporated by reference, in its entirety, into the current patent application as if fully set forth herein.

### TECHNICAL FIELD

The present disclosure relates to Schottky barrier diodes.

### BACKGROUND

A Schottky barrier diode (SBD) is a semiconductor diode formed by the junction of a semiconductor with a metal. The relatively low forward voltage of SBDs is desirable for applications requiring fast switching, such as power systems, radio frequency (RF) systems, and logic circuits. It is generally desirable to improve the performance and reduce the cost of SBDs, but it can be difficult to do so.

This background discussion is intended to provide related information, and is not necessarily prior art.

### SUMMARY OF THE INVENTION

In various examples of the present disclosure, a Schottky barrier diode (SBD) includes a volume of semiconductor material, a plurality of laterally spaced pockets of doped material, and a silicon layer. The volume of semiconductor material presents opposite first and second ends. The plurality of laterally spaced pockets of doped material extend into the volume of semiconductor material adjacent the first end. The silicon layer is located adjacent the first end between the pockets of doped material.

In various examples of the present disclosure, a method of making an SBD includes: growing a volume of semiconductor material on a cathode substrate, the volume of semiconductor material presenting a first end and a second end opposite the first end; implanting a silicon layer adjacent the first end; implanting a plurality of laterally spaced pockets of doped material adjacent the first end, the silicon layer extending between the pockets of doped material; and placing a Schottky metal at the first end and of the volume of semiconductor material adjacent the silicon layer and the pockets of doped material.

This summary is not intended to identify essential features of the examples, and is not intended to be used to limit the scope of the claims. These and other aspects of the present examples are described below in greater detail.

### BRIEF DESCRIPTION OF THE DRAWINGS

FIG. 1 is a cross-sectional elevation view of an example SBD;

FIG. 2 is an example method for making an SBD; and

FIGS. 3A-3E are cross-sectional elevation views of an example SBD at various stages of manufacture.

Unless otherwise indicated, the figures provided herein are meant to illustrate features of examples of this disclosure. These features are believed to be applicable in a wide variety of systems comprising one or more examples of this disclosure. As such, the figures are not meant to include all conventional features known by those of ordinary skill in the art to be required for the practice of the examples disclosed herein.

### DETAILED DESCRIPTION

In the following detailed description, reference is made to the accompanying drawings, which form a part hereof and in which are shown, by way of illustration, specific examples in which the present disclosure may be practiced. These examples are described in sufficient detail to enable a person of ordinary skill in the art to practice the present disclosure. However, other examples may be utilized, and structural, material, procedural, operational, and other changes may be made without departing from the scope of the disclosure. Unless clearly understood or expressly identified otherwise, structures, materials, procedures, operations, and other aspects described in the context of one example may be incorporated into other examples.

The illustrations presented herein are not meant to be actual views of any particular method, system, device, or structure, but are merely idealized representations that are employed to describe the examples of the present disclosure. The drawings presented herein are not necessarily drawn to scale. Similar structures or components in the various drawings may retain the same or similar numbering for the convenience of the reader; however, any similarity in numbering does not necessarily mean that the structures or components are necessarily identical in size, composition, configuration, or any other property.

Terms of relative location and direction (e.g., above, below, left, right, upper, lower, vertical, horizontal (or lateral)) may be used to facilitate the present descriptions of examples with reference to the figures, but unless clearly understood or expressly identified otherwise, these terms are not meant to be limiting with regard to location, direction, or overall orientation, and may, for example, change as a result of a change in overall orientation.

Thus, it will be readily understood that the components of the examples as generally described herein and illustrated in the drawings could be arranged and designed in a wide variety of different configurations. Thus, the following description of various examples is not intended to limit the scope of the present disclosure but is merely representative of various examples.

Examples provide a Schottky barrier diode (SBD). The example SBD may be suitable for high-voltage applications, and may operate at a voltage greater than one thousand (1,000) volts (V). More specifically, the example SBD may be rated for a voltage of around twelve hundred (1,200) V. It will be appreciated by one of ordinary skill in the art that the example SBD may be suitable for lower voltage applications without departing from the scope of the present disclosure. The example SBD may be implemented as a stand-alone device, or may be integrated with other devices (e.g., other diodes, transistors, and the like) as part of a semiconductor package.

The example SBD may include a volume of semiconductor material and a silicon layer implanted along a top end of the volume of semiconductor material. The volume of semiconductor material may include silicon carbide (SiC). Silicon has a bandgap of about 1.12 electron Volts (eV). SiC has a bandgap of about 3.26 eV. Accordingly, the silicon layer may reduce the forward voltage of the SBD due to the bandgap of silicon being lower than the bandgap of SiC. The silicon layer may additionally provide reduced leakage and increase the current carrying capacity of the SBD by lowering the forward voltage.

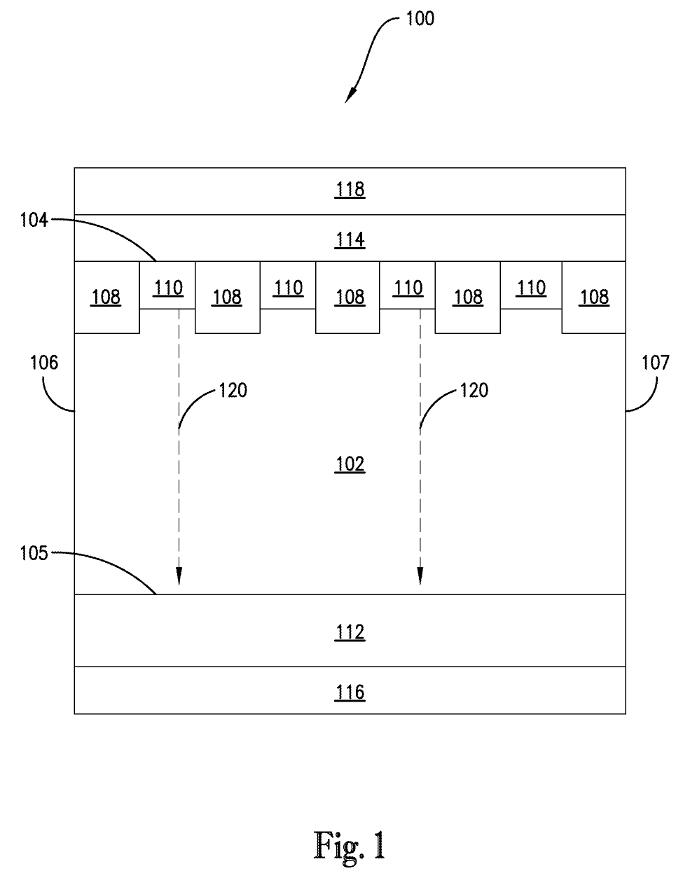

Referring to FIG. 1, an example of an SBD 100 is shown. The SBD 100 may generally include a volume of semiconductor material 102, laterally spaced pockets of doped material 108, and a silicon layer 110.

The volume of semiconductor material 102 may present a first end 104, a second end 105 opposite and vertically spaced from the first end 104, a first side 106, and a second side 107 opposite and laterally spaced from the first side 106. The volume of semiconductor material 102 may be constructed from or include an N-type epitaxial semiconductor material.

The pockets of doped material 108 may be constructed from or otherwise include a P+ material. The pockets of doped material 108 may be laterally spaced between the first side 106 and the second side 107. The pockets of doped material 108 may be implanted, deposited, or otherwise provided adjacent the first end 104. The pockets of doped material 108 may extend from the first end 104 toward the second end 105. The pockets of doped material 108 may be identical in shape and configuration and spaced equidistantly, although certain SBD examples contemplate variously shaped pockets, unequal spacing between the pockets, etc.

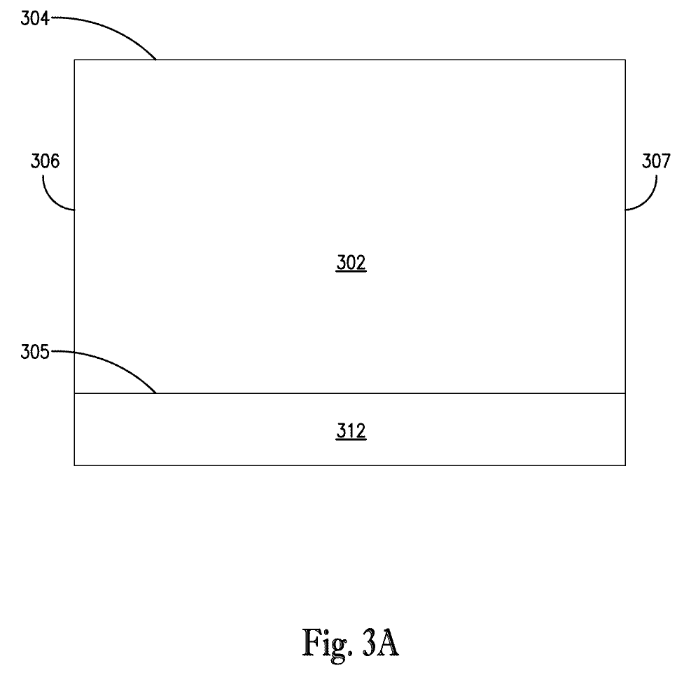

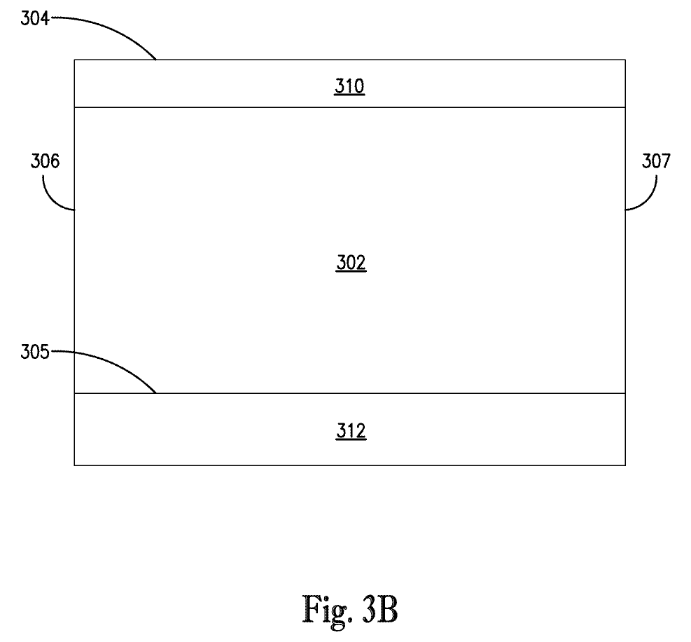

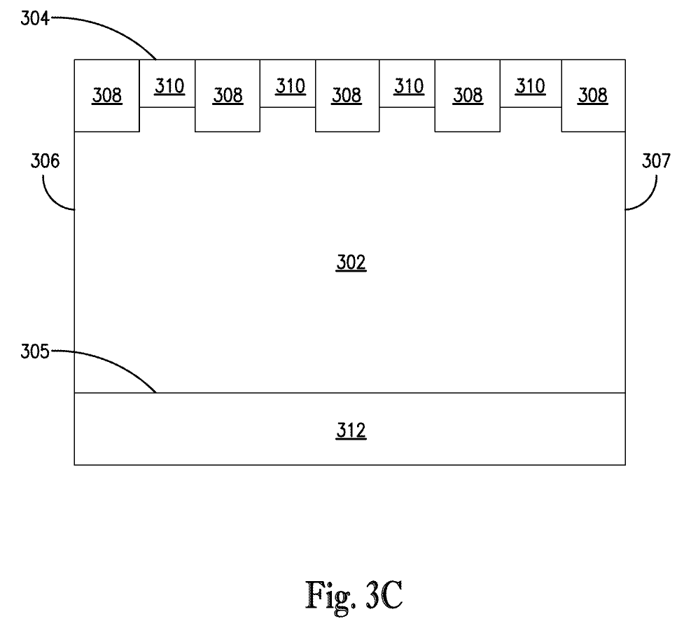

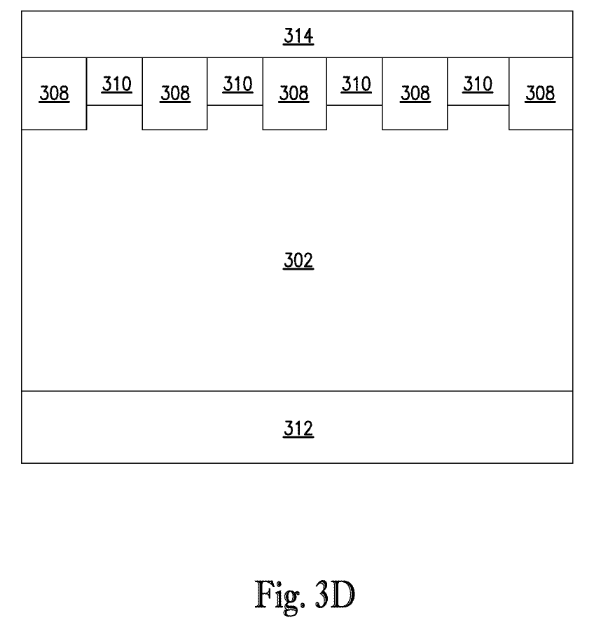

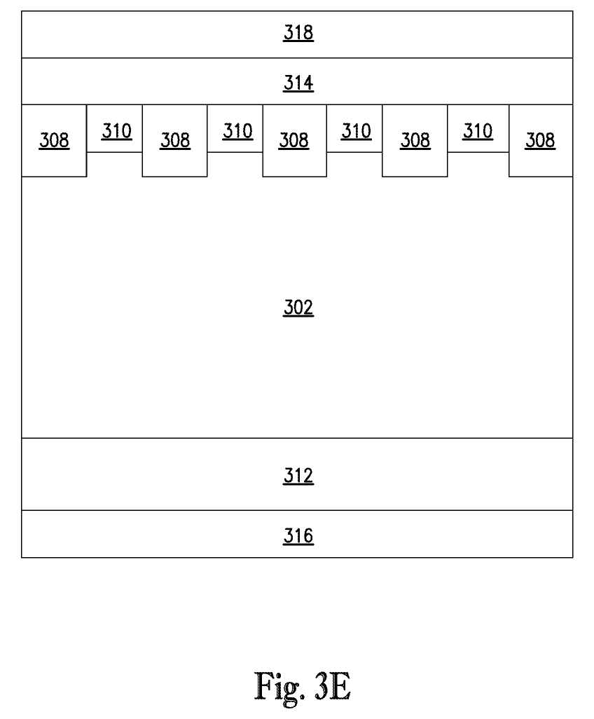

The silicon layer 110 may be implanted, deposited, or otherwise provided along the first end 104 to form a blanket layer of silicon across the first end 104 (e.g., as shown in FIG. 3B). In various examples, the silicon layer 110 may be implanted prior to formation of the pockets of doped material 108. The silicon layer 110 may extend between each of the pockets of doped material 108. The pockets of doped material 108 may extend closer to the second end 105 than the silicon layer 110. Other alternative dimensions and shapes of the doped material pockets and the silicon layer are within the ambit of certain aspects of the example SBD.

A cathode substrate 112 is located at the second end 105 of the volume of semiconductor material 102 and may be constructed from or include an N+ substrate material. The volume of semiconductor material 102 may be grown or otherwise formed on the cathode substrate 112. A cathode contact 116 may be located adjacent the cathode substrate 112 and spaced apart from the second end 105.

A Schottky metal 114 may include a Schottky barrier metal layer and a diffusion barrier metal layer. The Schottky barrier metal layer may include titanium, molybdenum, platinum, chromium, tungsten, aluminum, and combinations thereof. The diffusion barrier metal may include a metal alloy and may include titanium, molybdenum, platinum, chromium, tungsten, aluminum, nickel, and combinations thereof. The Schottky barrier metal layer may be adjacent the first end 104 and may contact both the pockets of doped material 108 and the silicon layer 110.

An anode contact 118 may be located above the Schottky metal 114 and spaced apart from the first end 104. The diffusion barrier metal may be interposed between the Schottky barrier metal layer and the anode contact 118. The anode contact 118 may include a conductive metal, such as aluminum, copper, nickel, or combinations thereof. In various examples, the anode contact 118 and the Schottky metal 114 may be formed of dissimilar metals although alternative examples contemplate forming the anode contact and Schottky metal of the same material.

Channels 120 may be provided by a channel portion of the volume of semiconductor material 102. The channels 120 extend through the volume of semiconductor material between the respective silicon layer 110 and the cathode substrate 112. The majority charge carriers may move and the electrical current may flow through the channels 120. It will be understood by one of ordinary skill in the art that the dashed lines representing the channels 120 are merely representative and charge carriers moving through the channels 120 do not necessarily follow a single, straight line.

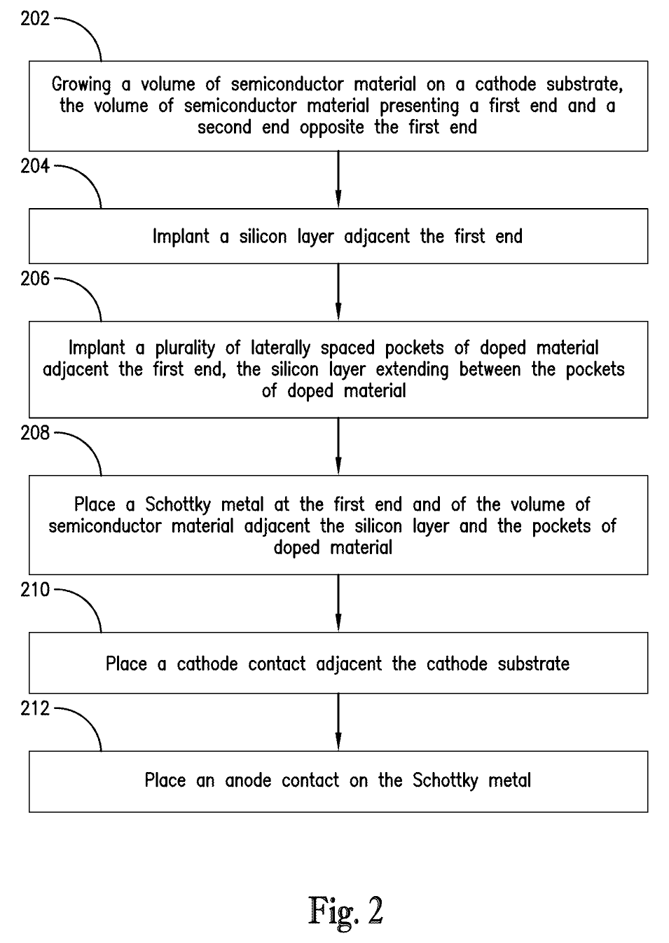

Referring to FIG. 2, an example of method 200 of manufacturing an SBD, such as the SBD 100 described above, may include the operations set forth below. Referring additionally to FIGS. 3A-E, example results of various operations are shown.

At operation 202, the method 200 begins by epitaxially growing a volume of semiconductor material 302, including a first end 304, a second end 305, a first side 306 and a second side 307, on a substrate material 312, as shown in FIG. 3A. The substrate material 312 may be a cathode substrate constructed from or otherwise including an N+ substrate material. The semiconductor material 302 may be an N-type semiconductor material. In various examples, the semiconductor material 302 may include silicon carbide (SiC).

At operation 204, a silicon layer 310 may be implanted adjacent the first end 304 of the semiconductor material 302, as shown in FIG. 3B. It is within the scope of the present disclosure that the silicon layer 310 may be formed within the semiconductor material by means other than implantation (e.g., by deposition, epitaxial growth, or otherwise). The silicon layer 310 may extend from the first end 304 toward the second end 305, with a length of the extension defining a thickness of the silicon layer 310. In various examples, the thickness of the silicon layer 310 may be about fifteen (15) to about one hundred (100) nanometers, although alternative silicon layer thickness is within the ambit of certain examples.

At operation 206, a plurality of laterally spaced pockets of doped material 308 may be implanted (e.g., via ion implantation), deposited, or otherwise provided adjacent the first end 304, as shown in FIG. 3C. The silicon layer 310 may extend between the doped material pockets 308. The doped material pockets 308 may extend from the first end 304 toward the second end 305. The doped material pockets 308 may extend toward the second end 305 beyond the silicon layer 310. The doped material pockets 308 may be constructed from or otherwise include a P+ material. According to certain examples, the doped material pockets may alternatively be formed of a single unitary implant which may or may not be subsequently modified (e.g., by etching or other suitable techniques).

It will be appreciated by one of ordinary skill in the art that the operation 204 (implanting the silicon layer 310) may occur after the operation 206 (implanting the doped material pockets 308), without departing from the scope of the present disclosure.

Referring to operation 208, a Schottky metal 314 may be placed at the first end 304 adjacent the silicon layer 310 and the pockets of doped material, as shown in FIG. 3D. The Schottky metal 314 may include a Schottky barrier metal layer and a diffusion barrier metal, as discussed in connection with the Schottky metal 114 of FIG. 1. The Schottky metal 314 may include titanium, molybdenum, platinum, chromium, tungsten, aluminum, nickel, and combinations thereof. The Schottky metal 314 may contact the silicon layer 310 and the doped material pockets 308.

Referring to operation 210, a cathode contact 316 is placed adjacent the cathode substrate 312. The cathode contact 316 may be formed of a conductive metal, such as aluminum, nickel, copper, and combinations thereof. The cathode contact 316 may contact the cathode substrate 312 and may be spaced apart from the second end 305. The cathode contact 316 may span the cathode substrate 312.

Referring to operation 212, an anode contact 318 is placed on the Schottky metal 314. The anode contact 318 may contact the Schottky metal 314. Specifically, the anode contact 318 may contact the diffusion metal layer of the Schottky metal 314, such that the diffusion metal layer is interposed between the anode contact 318 and the Schottky barrier metal. As noted above, the Schottky metal 314 and the anode contact 318 may be formed of dissimilar metals.

### FEATURE COMBINATIONS

In accordance with various examples of the present disclosure, a Schottky barrier diode (SBD) may include a volume of semiconductor material, a plurality of laterally spaced pockets of doped material, and a silicon layer. The volume of semiconductor material may present opposite first and second ends. The plurality of laterally spaced pockets of doped material may extend into the volume of semiconductor material adjacent the first end. The silicon layer may be located adjacent the first end between the pockets of doped material.

In accordance with various examples of the present disclosure, a method of making an SBD may include: growing a volume of semiconductor material on a cathode substrate, the volume of semiconductor material presenting a first end and a second end opposite the first end; implanting a silicon layer adjacent the first end; implanting a plurality of laterally spaced pockets of doped material adjacent the first end, the silicon layer extending between the pockets of doped material; and placing a Schottky metal at the first end and of the volume of semiconductor material adjacent the silicon layer and the pockets of doped material.

The preceding examples may include any one or more of the following features.

The SBD may include a Schottky metal located at the first end adjacent the pockets of doped material and the silicon layer.

The SBD may include an anode contact disposed on the Schottky metal.

The Schottky metal and the anode contact may be formed of dissimilar materials.

The Schottky metal may be selected from the group consisting of: titanium, molybdenum, platinum, chromium, tungsten, aluminum, and combinations thereof.

The SBD may include a cathode substrate located at the second end of the volume of semiconductor material.

The SBD may include a cathode contact adjacent the cathode substrate.

The volume of semiconductor material may comprise silicon carbide.

The volume of semiconductor material may include an N-type material. The pockets of doped material may include a P+ material. The cathode substrate may include an N+ material.

The pockets of doped material may extend towards the second end beyond the silicon layer.

The volume of semiconductor material may include an N-type material. The pockets of doped material may include a P+ material.

The method may comprise placing an anode contact on the Schottky metal.

The method may comprise forming the Schottky metal and the anode contact of dissimilar materials.

The method may comprise placing a cathode contact adjacent the cathode substrate.

The method may comprise extending the pockets of doped material toward the second end beyond the silicon layer.

The method may comprise forming the volume of semiconductor material of silicon carbide.

### GENERAL CONSIDERATIONS

While the present disclosure has been described herein with respect to certain illustrated examples, those of ordinary skill in the art will recognize and appreciate that the present disclosure is not so limited. Rather, many additions, deletions, and modifications to the illustrated and described examples may be made without departing from the scope of the disclosure as hereinafter claimed along with their legal equivalents. In addition, features from one example may be combined with features of another example while still being encompassed within the scope of the disclosure as contemplated by the inventors.

For example, although described herein with regard or in relation to one or more particular kinds of electronic devices (e.g., Schottky barrier diodes), the technology may be more broadly applicable to one or more other kinds of electronic devices as well. Additionally, the various example materials identified herein may, in some aspects, be replaced or supplemented with substantially any other suitable material. For example, the semiconductor material may include silicon carbide, gallium nitride, zinc oxide, or other suitable material.

It will be appreciated that the sides of the illustrated volume of semiconductor material are defined herein merely as an example, and may in various examples represent only a portion of semiconductor material relative to the illustrated device. In practice, the volume of semiconductor material may extend laterally (leftward and rightward when viewing FIG. 1) beyond the bounds illustrated in the drawings to present additional semiconductor material in which additional devices may be provided. (The semiconductor material may similarly extend inwardly or outwardly (relative to the lateral or cross-sectional direction depicted in FIG. 1) to present additional devices in a direction transverse to the lateral direction.) Such additional devices may be similarly or alternatively constructed to the illustrated SBD 100 or may be entirely different devices providing different operations or functions than the illustrated device 100. In other words, in practice, the illustrated device 100 may be just one of numerous devices spaced laterally and transversely within a single, integrally formed component, such as a wafer or integrated circuit (not shown).

Additionally, in general, unless otherwise specified or unless one with ordinary skill in the art would understand otherwise, doping concentrations (measured in parts per cubic centimeter) for contact implants may be approximately between 10^18 and 10^22; doping concentrations for channel and threshold forming implants may be approximately between ₁₀^16 and 10^17; doping concentrations for shielding implants may be approximately between 10^17 and 10^19; and doping concentrations for conductivity improvement implants may be approximately between ₁₀^₁₆ and ₁₀^17. Relatedly, a structure or region may contain two or more different doping doses.

In this description, references to "one embodiment," "an embodiment," "embodiments," "an example," "one example," or "examples" mean that the feature or features being referred to are included in at least one embodiment or example of the technology. Separate references to "one embodiment," "an embodiment," "embodiments," "an example," "one example," or "examples" in this description do not necessarily refer to the same embodiment or example and are also not mutually exclusive unless so stated and/or except as will be readily apparent to those skilled in the art from the description. For example, a feature, structure, act, etc. described in one embodiment may also be included in other embodiments but is not necessarily included. Thus, the current technology can include a variety of combinations and/or integrations of the embodiments described herein.

Throughout this specification, plural instances may implement components, operations, or structures described as a single instance. Although individual operations of one or more methods are illustrated and described as separate operations, one or more of the individual operations may be performed concurrently, and nothing requires that the operations be performed in the order illustrated. Structures and functionality presented as separate components in example configurations may be implemented as a combined structure or component. Similarly, structures and functionality presented as a single component may be implemented as separate components. These and other variations, modifications, additions, and improvements fall within the scope of the subject matter herein, unless otherwise expressly stated and/or readily apparent to those skilled in the art from the description.

As used herein, the terms "comprises," "comprising," "includes," "including," "has," "having" or any other variation thereof, are intended to cover a non-exclusive inclusion. For example, a process, method, article, or apparatus that comprises a list of elements is not necessarily limited to only those elements but may include other elements not expressly listed or inherent to such process, method, article, or apparatus. Further, unless expressly stated to the contrary, "or" refers to an inclusive or and not to an exclusive or. For example, a condition A or B is satisfied by any one of the following: A is true (or present) and B is false (or not present), A is false (or not present) and B is true (or present), and both A and B are true (or present).

The patent claims at the end of this patent application are not intended to be construed under 35 U.S.C. § 112(f) unless traditional means-plus-function language is expressly recited, such as "means for" or "step for" language being explicitly recited in the claim(s).

What is claimed is:

1. A Schottky barrier diode (SBD), comprising:
a volume of semiconductor material presenting opposite first and second ends;
a plurality of laterally spaced pockets of doped material extending into the volume of semiconductor material adjacent the first end; and
a silicon layer located adjacent the first end between the pockets of doped material.

2. The SBD of claim 1, comprising:
a Schottky metal located at the first end adjacent the pockets of doped material and the silicon layer.

3. The SBD of claim 2, comprising:
an anode contact disposed on the Schottky metal.

4. The SBD of claim 3,
the Schottky metal and the anode contact being formed of dissimilar materials.

5. The SBD of claim 2,
the Schottky metal being selected from the group consisting of: titanium, molybdenum, platinum, chromium, tungsten, aluminum, and combinations thereof.

6. The SBD of claim 1, comprising:
a cathode substrate located at the second end of the volume of semiconductor material.

7. The SBD of claim 6, comprising:
a cathode contact adjacent the cathode substrate.

8. The SBD of claim 7,
the volume of semiconductor material comprising silicon carbide.

9. The SBD of claim 8,
the volume of semiconductor material including an N-type material,
the pockets of doped material including a P+ material,
the cathode substrate including an N+ material.

10. The SBD of claim 9,
the pockets of doped material extending towards the second end beyond the silicon layer.

11. The SBD of claim 1,
the pockets of doped material extending towards the second end beyond the silicon layer.

12. The SBD of claim 1,
the volume of semiconductor material comprising silicon carbide.

13. The SBD of claim 12,
the volume of semiconductor material including an N-type material,
the pockets of doped material including a P+ material.

14. The SBD of claim 13,
the pockets of doped material extending towards the second end beyond the silicon layer.

15. A method of making a Schottky barrier diode (SBD), comprising:
growing a volume of semiconductor material on a cathode substrate, the volume of semiconductor material presenting a first end and a second end opposite the first end;
implanting a silicon layer adjacent the first end;
implanting a plurality of laterally spaced pockets of doped material adjacent the first end, the silicon layer extending between the pockets of doped material; and
placing a Schottky metal at the first end and of the volume of semiconductor material adjacent the silicon layer and the pockets of doped material.

16. The method of claim 15, comprising:
placing an anode contact on the Schottky metal.

17. The method of claim 16,
forming the Schottky metal and the anode contact of dissimilar materials.

18. The method of claim 15, comprising:
placing a cathode contact adjacent the cathode substrate.

19. The method of claim 15,
extending the pockets of doped material toward the second end beyond the silicon layer,
forming the volume of semiconductor material of silicon carbide.

20. The method of claim 15,
the Schottky metal being selected from the group consisting of: titanium, molybdenum, platinum, chromium, tungsten, aluminum, and combinations thereof.
